(19) United States
(12) Patent Application Publication
(10) Pub. No.: US 2025/0224548 A1
(43) Pub. Date: Jul. 10, 2025

(54) SLANTED OPTICAL GRATINGS

(71) Applicant: NIL Technology ApS, Kongens Lyngby (DK)

(72) Inventors: Niklas Hansson, Askim (SE); James Eilertsen, Naerum (DK)

(21) Appl. No.: 18/853,999

(22) PCT Filed: Mar. 31, 2023
(86) PCT No.: PCT/EP2023/058566

§ 371 Date: Oct. 3, 2024

Related U.S. Application Data
(60) Provisional application No. 63/328,856, filed on Apr. 8, 2022.

(51) Int. Cl. G02B 5/18; G03F 7/00; G03F 7/16

(52) U.S. Cl. CPC G02B 5/1857; G03F 7/0002; G03F 7/0005; G03F 7/168

(57) ABSTRACT

The present disclosure describes optical gratings and devices incorporating the optical gratings, as well as techniques for fabricating the optical gratings. An example method includes imprinting an imprint material with a pattern defining positions and angles for optical gratings, depositing a grating material onto the imprint material, and subsequently removing the imprint material to form slanted optical gratings.

### FIELD OF THE DISCLOSURE

The present disclosure relates to optical gratings.

### BACKGROUND

Diffraction gratings are periodic structures that diffract light in only a certain number of discrete directions. Slanted gratings, for example, are a form of line gratings, where the profile of each line is tilted. In some cases, an advantage provided by slanted gratings is that by a proper choice of dimensions, tilt angle and material, a significant percentage of the light can be directed into a single diffraction order. Thus, slanted gratings are sometimes used for coupling light into optical light guides due to their high efficiency in a certain diffraction order.

Slanted gratings can be used, for example, in applications where efficient redirecting of light is important. An example application of slanted gratings is for transparent waveguides in augmented and mixed reality (AR/MR) head mounted displays, where light from an image generator is coupled into the waveguide at one end and coupled out of the waveguide and directed to the eye of the observer at the other end. The gratings act as high efficiency in-and out-coupling gratings.

In addition to waveguides, slanted gratings may be used in other applications, for example, where high efficiency of a single diffraction order is desired.

### SUMMARY

The present disclosure describes optical gratings and devices incorporating the optical gratings, as well as techniques for fabricating the optical gratings. The gratings can be slanted and, in some instances, may form a relatively high angle with respect to a surface of the substrate supporting the gratings.

For example, in one aspect, a method includes imprinting an imprint material with a pattern defining positions and angles for optical gratings, depositing a grating material onto the imprint material, and subsequently removing the imprint material to form slanted optical gratings.

Some implementations include one or more of the following features. For example, in some cases, the imprint material comprises a soluable imprint resist. The imprint material may be, for example, polymethyl methacrylate (PMMA).

In some implementations, the grating material includes titanium dioxide or aluminum oxide. Depositing the grating material can include, for example, evaporating the grating material by resistive or e-beam evaporation. In accordance with some implementations, the method includes coating a surface of a substrate with the imprint material before imprinting the imprint material, wherein the slanted optical gratings form an angle a with the surface of the substrate, where 20°≤α≤60°.

In some cases, the method includes coating a surface of a substrate with the imprint material before imprinting the imprint material, and performing a descum etch process to remove residual portions of the imprint material from the surface of the substrate prior to evaporating the grating material onto the imprint material. In some instances, the descum etch process includes an oxygen plasma etch.

In some implementations, the method includes forming supports for the gratings, wherein the supports are composed of a same material as the gratings and are formed at a same time as the gratings. In some implementations, the method includes forming openings in a surface of a substrate on which the gratings are to be formed, and subsequently depositing grating material in the openings. The grating material in the openings provides adhesion of the gratings to the substrate. The grating material in the openings can be deposited at a same time as, and can have a same composition as, the grating material deposited onto the imprint material. In some implementations, a refractive index of the substrate matches a refractive index of the gratings.

The present disclosure also describes a method that includes imprinting an imprint material with a pattern defining positions and angles for optical gratings, curing the imprinted imprint material, depositing a grating material onto the cured imprint material, wherein an index of refraction of the cured imprint material is 1.3 or less.

Some implementations include one or more of the following features. For example, in some cases, the imprint material includes a soluable imprint resist. The imprint material can be, for example, polymethyl methacrylate (PMMA).

In some implementations, the grating material includes titanium dioxide or aluminum oxide. Depositing the grating material can include, for example, evaporating the grating material by resistive or e-beam evaporation.

In some instances, the method includes coating a surface of a substrate with the imprint material before imprinting the imprint material, wherein the slanted optical gratings form an angle a with the surface of the substrate, where 20°≤α≤60°. In some instances, the method includes coating a surface of a substrate with the imprint material before imprinting the imprint material, and performing a descum etch process to remove residual portions of the imprint material from the surface of the substrate prior to evaporating the grating material onto the imprint material. The descum etch process can include, for example, an oxygen plasma etch.

In some implementations, the method includes forming supports for the gratings, wherein the supports are composed of a same material as the gratings and are formed at a same time as the gratings.

Some implementations include one or more of the following advantages. For example, in some cases, the techniques described in the present disclosure can help overcome challenges with known mass production techniques that use replication to fabricate gratings with relatively large overhangs. In particular, in at least some implementations, the imprinting operation itself does not produce an overhang. Instead, the remaining imprint material is removed, if at all, after depositing the grating material. Such manufacturing techniques can help increase the yield of the resulting devices.

The details of one or more implementations of the subject matter described in this specification are set forth in the accompanying drawings and the description below. Other aspects, features and advantages will be readily apparent from the following detailed description, the accompanying drawings, and the claims.

### BRIEF DESCRIPTION OF THE DRAWINGS

FIGS. 1A through 1E describe an example method of fabricating slanted optical gratings.

FIG. 2 illustrates an example in which the slanted gratings partially overlap one another.

FIGS. 3A through 3E describe another example method of fabricating slanted optical gratings.

FIG. 4A illustrates an example of a slanted optical grating that includes a structural support.

FIGS. 4B through 4D illustrates steps in the fabrication of the optical grating of FIG. 4A, where FIGS. 4B through 4D are rotated laterally by ninety degrees with respect to the orientation of FIG. 4A.

FIGS. 5A through 5C illustrate yet another method of fabricating slanted optical gratings.

FIGS. 6A through 6C illustrate another method of fabricating slanted optical gratings that include a structural support.

FIG. 7 illustrates an example a waveguide display that includes an optical slanted grating structure.

### DETAILED DESCRIPTION

The present disclosure describes optical gratings and devices incorporating the optical gratings, as well as techniques for fabricating the optical gratings. The gratings can be slanted and may form a relatively high angle with respect to a surface of the substrate supporting the gratings.

As described in greater detail below, the techniques can include imprinting a resist or (other imprint material) with a pattern defining the positions and angles of the gratings, and evaporating a grating material onto the resist to form slanted optical gratings. In some implementations, the resist subsequently is removed. Depending on the application, the gratings can be used in a transmissive mode (i.e., a mode in which light passes through the gratings) or a reflective mode (i.e., a mode in which light is reflected by the gratings). The techniques can be used, for example, to enable the manufacture of high-angle gratings in high refractive index materials. In some instances, the gratings have relatively large overhangs that may be difficult to fabricate using other techniques.

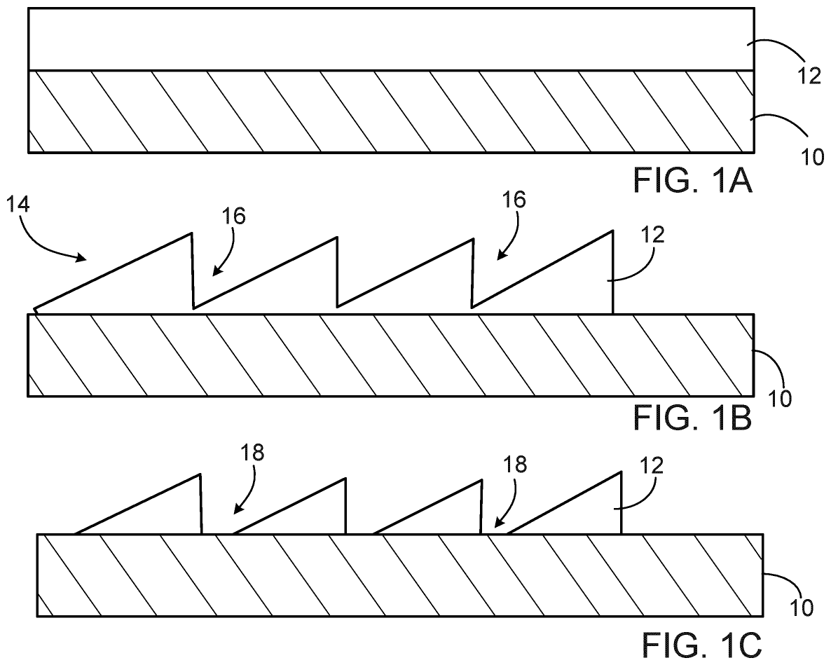

FIGS. 1A through 1E describe an example method for fabricating slanted optical gratings. As shown in FIG. 1A, a surface of a substrate 10 is coated with an imprint material 12. In some implementations (e.g., transmissive mode applications), the substrate 10 is composed, for example, of a material such as glass that is transparent to the operating wavelength or range of wavelengths of interest (e.g., 940 nm, or a range of wavelengths in the infra-red part of the electromagnetic spectrum). The imprint material 12 can be, for example, a soluble imprint resist (e.g., polymethyl methacrylate (PMMA)). In some implementations, the imprint material 12 may have a very low refractive index (e.g., 1.3 or less). Next, as illustrated by FIG. 1B, the imprint material 12 is patterned by imprinting it with a tool (e.g., a mold). The imprint tool can be brought into contact with, and pressed into, the material 12 so as to imprint a pattern 14 into the material 12 (e.g., by nanoimprint lithography (NIL). The tool can include a structured surface that corresponds to the pattern 14 for the lateral locations and the angles of the gratings, and that can be transferred (e.g., by imprinting) to the imprint material 12 on the substrate 10. In general, the pattern 14 imprinted into the imprint layer 12 will be a negative of the structured pattern in the surface of the tool. As shown in the example of FIG. 1B, the imprinted pattern corresponds to blazed gratings, whose surface is slanted with respect to the surface of the substrate 10.

In some cases, the tool can be used as part of a mass production manufacturing process. Manufacturing the optical gratings may take place, in some instances, at a wafer-level in which tens, hundreds, or even thousands of grating devices are formed in parallel using the same tool.

After imprinting the imprint material 12, the imprinted material can be cured, for example, by ultra-violet (UV) and/or thermal techniques. In some instances, a descum etch process is performed to remove residual imprint material (e.g., resist scum) 16 on the surface of the substrate 10. That is, the descum etch can remove residual resist 16 that is present between the imprinted material 12 that corresponds to the positions of adjacent gratings. Preferably, the descum etch, which can be implemented, for example, as an oxygen plasma etch, is used to expose portions 18 of the substrate surface so as to improve adherence of the subsequently-deposited grating material. In some instances, it can be advantageous to use an anisotropic etch. Nevertheless, as the descum etch can be of relatively short duration, an isotropic etch can be used in some cases.

As illustrated by FIG. 1D, a grating material 20 is deposited onto the slanted surfaces of the imprinted material 12. The deposited grating material 20 also extends beyond the imprinted material 12 defining the positions of the gratings such that substantially horizontal portions 22 of the grating material are deposited onto the exposed portions 18 of the substrate surface. As noted above, in some implementations, this feature can help improve adherence of the grating material.

Deposition of the grating material can be accomplished, for example, by resistive or e-beam evaporation, with the substrate 10 tilted slightly in relation to the source. For transmissive applications, the grating material 20 should be substantially transparent to the wavelength or range of wavelengths of interest (e.g., 940 nm, or a range of wavelengths in the infra-red part of the electromagnetic spectrum). Examples of the grating material 20, for some implementations, are titanium dioxide or aluminum oxide. Other materials may be used for some implementations. For reflective applications, the grating material 20 should substantially reflect the operating wavelength or range of wavelengths.

The arrangement of FIG. 1D can be configured to be used directly as an optical element (e.g., a transmissive or reflective grating), or can be configured to be used as a master (e.g., tool or mold). That is, in some instances, the method results in a master (e.g., tool or mold), which can be used to form multiple optical grating. In some instances, the master can be used to replicate sub-masters, which in turn may be used to replicate the optical gratings. That is, optical grating devices can be replicated directly from the sub-master or from higher generation sub-masters.

Further, in some implementations (e.g., for reflective applications), it may not be necessary to remove the remaining imprinted material 12. Instead, the structure of FIG. 1D can be separated (e.g., by dicing the substrate 10) into individual optical elements each of which includes one or more slanted optical gratings 24. Such implementations can be useful, for example, where the refractive index of the cured imprinted material 12 is 1.3 or less.

In some implementations, the remaining imprinted material 12 of FIG. 1D is removed, for example, using a solvent (e.g., acetone). The result is illustrated in FIG. 1E, which shows multiple slanted optical gratings 24 on the substrate 10. Such an arrangement can be particularly advantageous for transmissive applications in which the light passes through the gratings 24 and the substrate 10.

As noted above, the foregoing fabrication techniques allow for the gratings 24 to be slanted at a relatively high angle. For example, in some instances, the gratings 24 form an angle a with the surface of the substrate 10, where 20°≤α≤60°. In some implementations, the gratings 24 may be slanted at some other angle with respect to the surface of the substrate 10. Further the techniques can be used, for example, to enable the manufacture of high-angle gratings in high refractive index materials. In some instances, the gratings have relatively large overhangs that may be difficult to fabricate using known techniques.

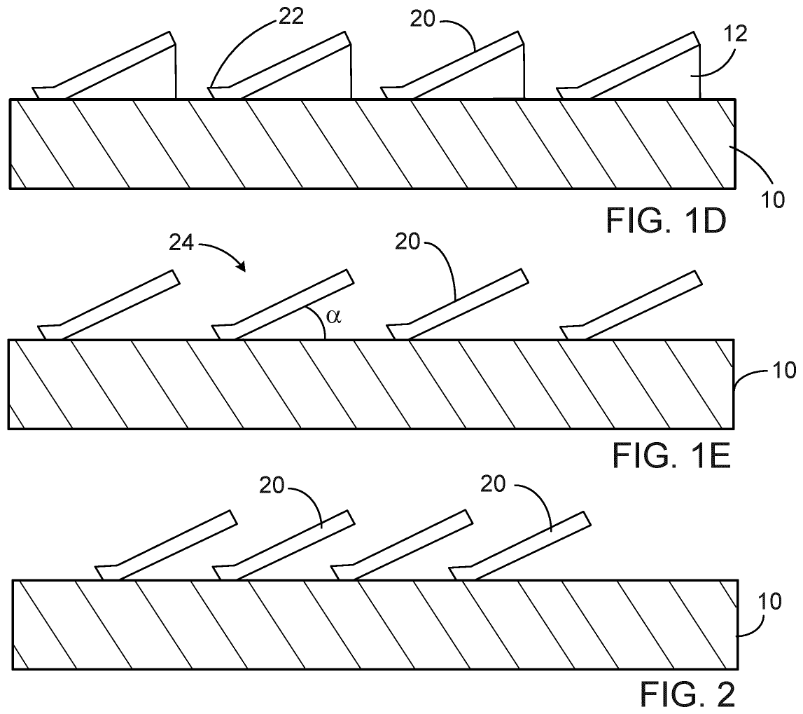

In some implementations, a thermal process (e.g., heating) can be applied to the substrate 10 so as to shrink the lateral dimensions of the substrate and cause the optical gratings 20 to overlap one another partially, as shown in FIG. 2.

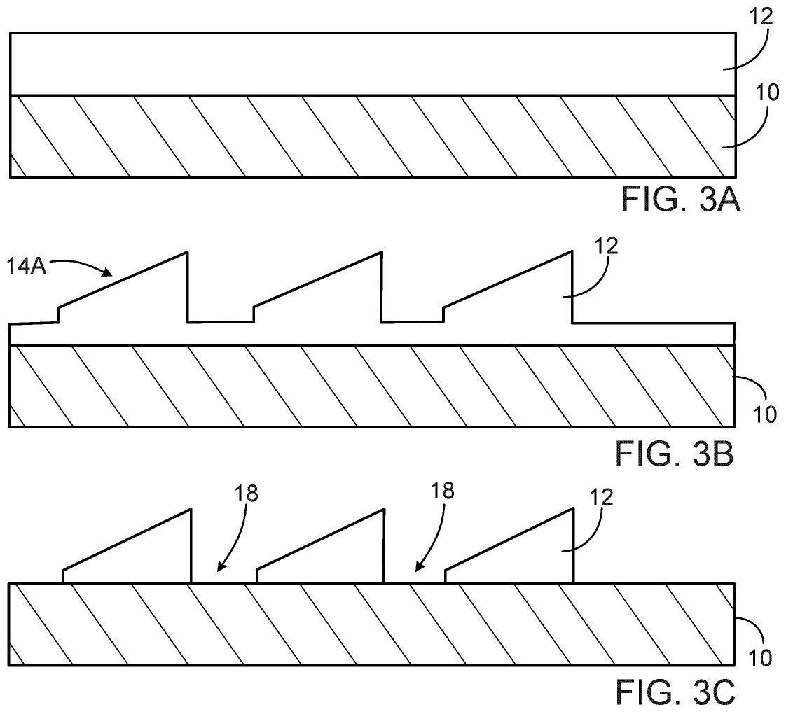

FIGS. 3A through 3E illustrate another example method for fabricating slanted optical gratings. The method of FIGS. 3A through 3E is similar to that described above in connection with FIGS. 1A through 1E, except that each grating 20 is connected to the substrate 10 by a substantially vertical portion 22A of grating material rather than a substantially horizontal portion 22 (see FIGS. 3D and 3E). That is, FIG. 3A illustrates a layer of imprint material 12 on a substrate 10; FIG. 3B illustrates the structure after imprinting the imprint layer 12 using an imprint tool (e.g., a mold); FIG. 3C illustrates the structure following a descum etch that exposes portions 18 of the surface of the substrate 10; FIG. 3D illustrates the structure following evaporation of the grating material 20; and FIG. 3E illustrates the resulting grating structure 24 after removal of the remaining imprinted material 12. In this case, the tool includes a structured surface that corresponds to the pattern 14A for the lateral locations and the angles of the gratings, and that can be transferred (e.g., by imprinting) to the imprint material 12 on the substrate 10. In other respects, the method illustrated by FIGS. 3A-3E can be substantially the same as the method illustrated by FIGS. 1A-1E.

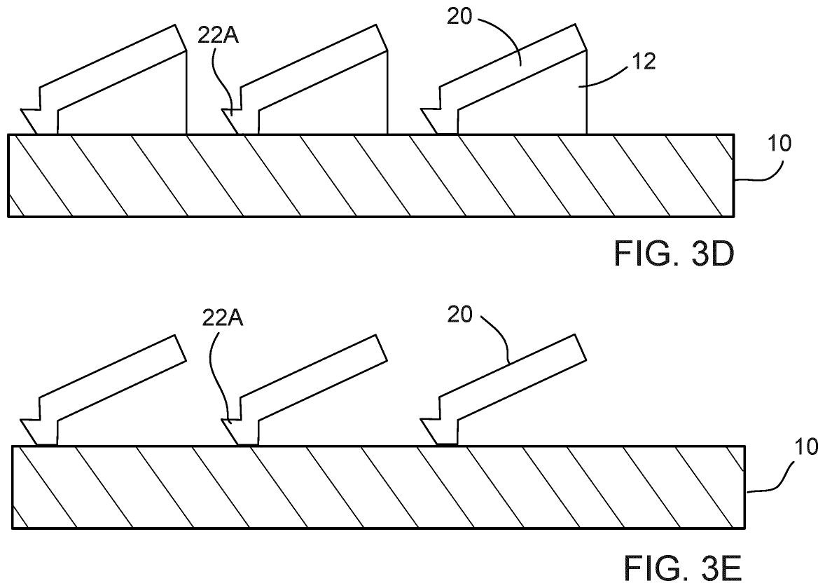

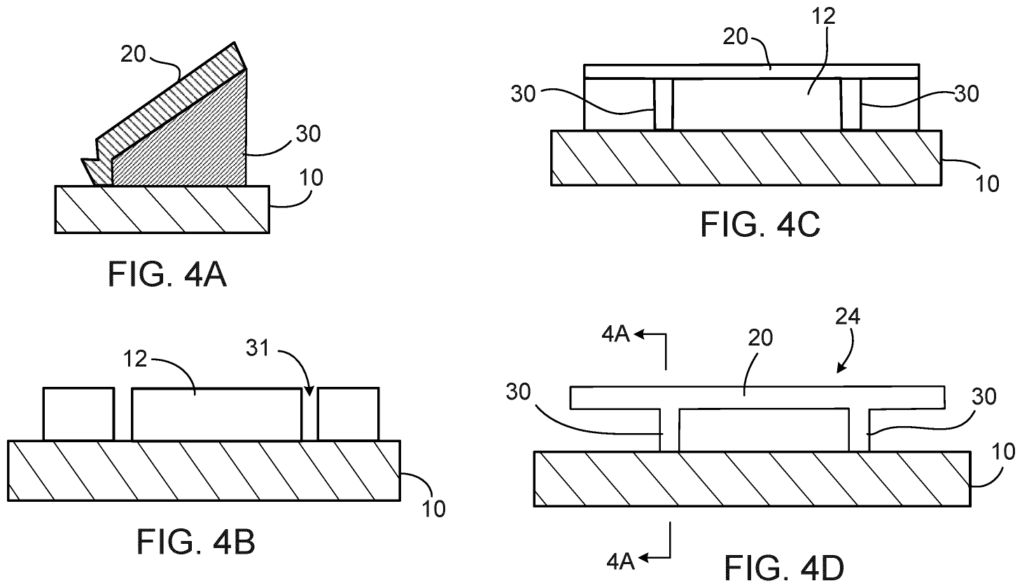

In some implementations, as illustrated in FIG. 4A, structural supports 30 can be provided to improve the mechanical stability of the optical gratings 20. The supports 30 can be composed, for example, of the same material as the gratings 20 (e.g., titanium dioxide or aluminum oxide), and can be formed at the same time as the gratings. For example, the structured surface of the imprint tool used can include features corresponding to the supports 30. When the tool (e.g., mold) is pressed into the imprint material 12, it forms openings 31 (see FIG. 4B) that subsequently can be filled with the grating material to form the supports 30 (see FIG. 4C). The remaining imprinted material 12 then can be removed, with the resulting grating structure 24 as shown in FIG. 4D.

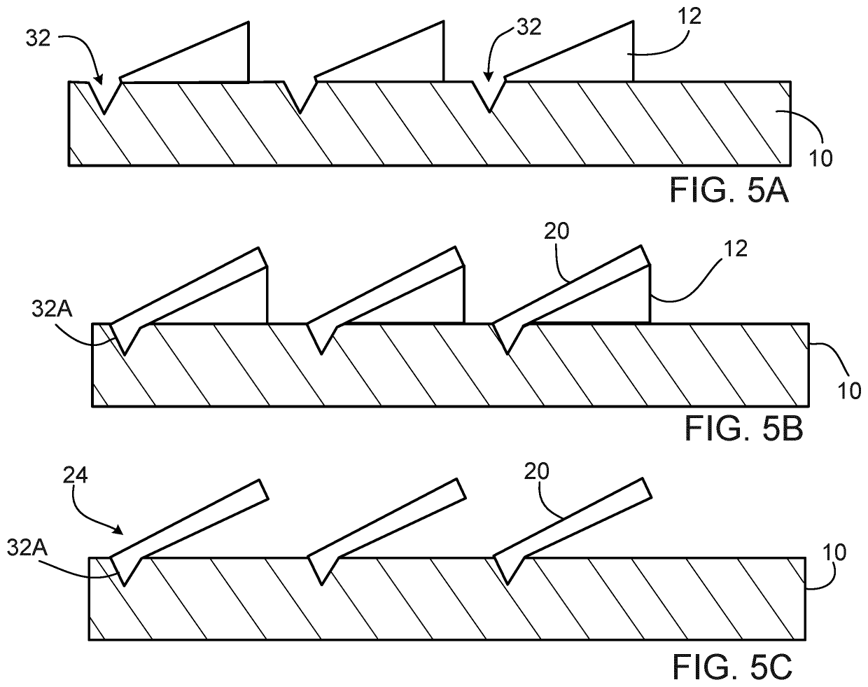

In some implementations, small openings can be formed in the surface of the substrate and subsequently filled with grating material to help improve adhesion of the grating material to the substrate and to improve mechanical stability. In such implementations, it can be advantageous to match the refractive index of the substrate to the refractive index of the gratings. An example is illustrated in FIGS. 5A though 5C. As shown in FIG. 5A, openings (e.g., voids, channels, troughs) 32 can be etched into the surface of the substrate 10. The openings 32 are located in areas of the substrate surface that are adjacent to positions where the gratings subsequently are to be formed. As shown in FIG. 5B, the grating material then is deposited (e.g., by resistive or e-beam evaporation) to form the gratings 20 themselves as well as to fill the openings 30. In FIG. 5B, the grating material-filled openings are indicated by 32A. Then, the remaining imprinted material 12 can be removed (e.g., using a solvent). The result is illustrated in FIG. 5C, which shows multiple slanted optical gratings 24 on the substrate 10. In some implementations, structural supports (e.g., supports 30 as shown in FIGS. 4A-4B) can be provided for the implementation of FIGS. 5A-5C.

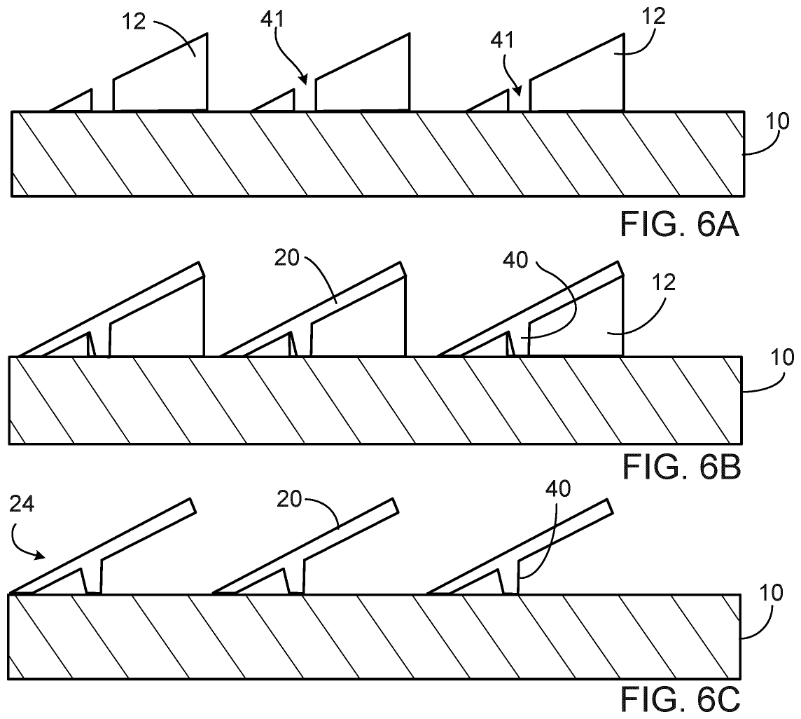

FIGS. 6A-6C illustrate another implementation that includes formation of mechanical supports 40 to improve the mechanical stability of the optical gratings 20. Here as well, the supports 40 can be composed, for example, of the same material as the gratings 20 (e.g., titanium dioxide or aluminum oxide), and can be formed at the same time as the gratings. For example, the structured surface of the imprint tool can include features corresponding to the supports 40. When the tool (e.g., mold) is pressed into the imprint material 12, it forms openings 41 (see FIG. 6A) that subsequently can be filled with the grating material to form the supports 40 (see FIG. 6B). The remaining imprinted material 12 then can be removed, with the resulting grating structure 24, including slanted optical gratings 20, as shown in FIG. 6C.

The foregoing solutions can, in some cases, help overcome challenges with known mass production techniques that use replication to fabricate gratings with relatively large overhangs. In at least some known techniques, fabricating optical gratings that have a large overhang tends to result in low yield, thereby making the process unsuitable of mass production. The present techniques can help obviate such issues because the imprinting operation itself does not produce an overhang. Instead, the remaining imprinted resist (or other imprint material) is removed, if at all, after depositing the grating material.

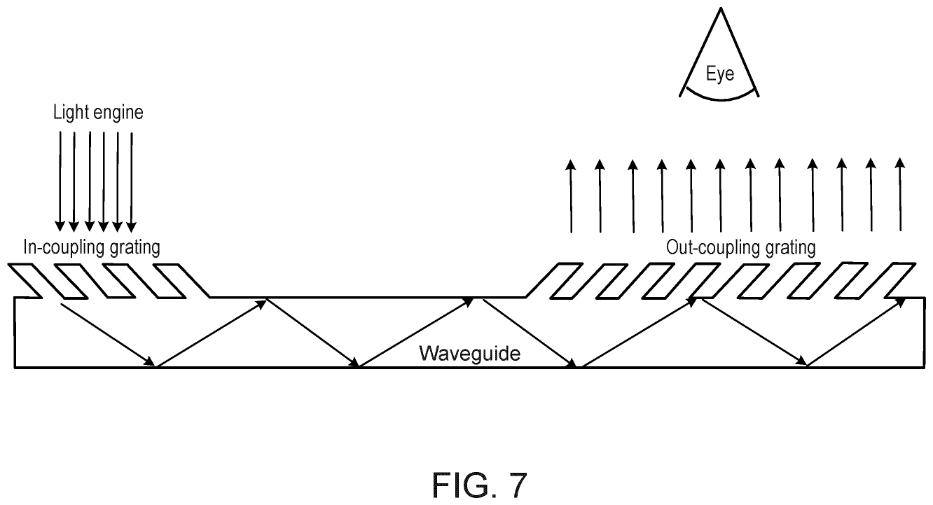

FIG. 7 illustrates an example application in which an optical slanted grating structure, such as described above, is integrated into a waveguide display. In the illustrated example, light from a light source (e.g., a light engine) is directed, through a first in-coupling optical grating, into an optical waveguide. The light travels through the waveguide and exits through a second out-coupling optical grating.

In general, the slanted optical gratings described in this disclosure can be used, for example, in applications where efficient redirecting of light is important. An example application of the slanted gratings is for transparent waveguides in augmented and mixed reality (AR/MR) head mounted displays, where light from an image generator is coupled into the waveguide at one end and coupled out of the waveguide and directed to the eye of the observer at the other end. The gratings act as high efficiency in-and out-coupling gratings. In addition to waveguides, the slanted gratings may be used in other applications, for example, where high efficiency of a single diffraction order is desired.

While this document contains many specific implementation details, these should not be construed as limitations on the scope of any inventions or of what may be claimed, but rather as descriptions of features specific to particular embodiments. Certain features that are described in this document in the context of separate embodiments can also can be implemented in combination in a single embodiment. Conversely, various features that are described in the context of a single embodiment can also can be implemented in multiple embodiments separately or in any suitable sub-combination. Various modifications can be made to the foregoing examples. Accordingly, other implementations also are within the scope of the claims

1. A method comprising:
imprinting an imprint material with a pattern defining positions and angles for optical gratings;
depositing a grating material onto the imprint material; and
subsequently removing the imprint material to form slanted optical gratings.

2. The method of claim 1 wherein the imprint material comprises a soluble imprint resist.

3. The method of claim 1 wherein the imprint material is polymethyl methacrylate (PMMA).

4. The method of claim 1 wherein the grating material comprises titanium dioxide or aluminum oxide.

5. The method of claim 1 wherein depositing the grating material includes evaporating the grating material by resistive or e-beam evaporation.

6. The method of claim 1 including:
coating a surface of a substrate with the imprint material before imprinting the imprint material, wherein the slanted optical gratings form an angle α with the surface of the substrate, where 20°≤α≤60°.

7. The method of claim 1 further including:
coating a surface of a substrate with the imprint material before imprinting the imprint material; and
performing a descum etch process to remove residual portions of the imprint material from the surface of the substrate prior to evaporating the grating material onto the imprint material.

8. The method of claim 7 wherein the descum etch process includes an oxygen plasma etch.

9. The method of claim 1 further including:
forming supports for the gratings, wherein the supports are composed of a same material as the gratings and are formed at a same time as the gratings.

10. The method of claim 1 further including:
forming openings in a surface of a substrate on which the gratings are to be formed; and
subsequently depositing grating material in the openings, wherein the grating material in the openings provides adhesion of the gratings to the substrate, and wherein the grating material in the openings is deposited at a same time as, and has a same composition as, the grating material deposited onto the imprint material.

11. The method of claim 10 wherein a refractive index of the substrate matches a refractive index of the gratings.

12. A method comprising:
imprinting an imprint material with a pattern defining positions and angles for optical gratings;
curing the imprinted imprint material; and
depositing a grating material onto the cured imprint material,
wherein an index of refraction of the cured imprint material is 1.3 or less.

13. The method of claim 12 wherein the imprint material comprises a soluble imprint resist.

14. The method of claim 12 wherein the imprint material is polymethyl methacrylate (PMMA).

15. The method of claim 12 wherein the grating material comprises titanium dioxide or aluminum oxide.

16. The method of claim 12 wherein depositing the grating material includes evaporating the grating material by resistive or e-beam evaporation.

17. The method of claim 12 including:
coating a surface of a substrate with the imprint material before imprinting the imprint material,
wherein the slanted optical gratings form an angle α with the surface of the substrate, where 20°≤α≤60°.

18. The method of claim 12 further including:
coating a surface of a substrate with the imprint material before imprinting the imprint material; and
performing a descum etch process to remove residual portions of the imprint material from the surface of the substrate prior to evaporating the grating material onto the imprint material.

19. The method of claim 18 wherein the descum etch process includes an oxygen plasma etch.

20. The method of claim 12 further including:
forming supports for the gratings, wherein the supports are composed of a same material as the gratings and are formed at a same time as the gratings.
